(19) United States
(12) Patent Application Publication
(10) Pub. No.: US 2026/0096370 A1
(43) Pub. Date: Apr. 2, 2026

(54) ELEMENT CHIP PRODUCTION METHOD AND BONDED BODY PRODUCTION METHOD

(71) Applicant: Panasonic Intellectual Property Management Co., Ltd., Osaka (JP)

(72) Inventors: Shogo OKITA, HYOGO (JP); Toshiyuki TAKASAKI, OSAKA (JP); Hidehiko KARASAKI, HYOGO (JP); Yoshimasa INAMOTO, KYOTO (JP); Atsushi HARIKAI, SAGA (JP)

(21) Appl. No.: 19/342,779

(22) Filed: Sep. 29, 2025

(30) Foreign Application Priority Data
Sep. 30, 2024 (JP) 2024-171189

(51) Int. Cl. H01L 21/78; H01L 21/3065; H01L 23/00

(52) U.S. Cl. CPC H10P 54/00; H10P 50/242; H10W 80/016; H10W 80/312; H10W 80/327

(57) ABSTRACT

An element chip production method includes: a preparation step of preparing a substrate having a first principal surface and a second principal surface and including a first layer being a semiconductor layer and a second layer formed on the first principal surface side of the first layer and including an insulator, the substrate having a plurality of element regions and a division region defining the element regions; a first protective layer formation step of forming, on the upper surface of the second layer, a first protective layer having a first opening from which the division region is exposed; a first groove formation step of forming a first groove by performing etching on a part of the second layer exposed from the first opening; a second protective layer formation step of forming a second protective layer on the surface of the second layer; a laser grooving step; and a dicing step.

### CROSS REFERENCE TO RELATED APPLICATION

The present application is based on and claims priority under 35 U.S.C. § 119 with respect to the Japanese Patent Application No. 2024-171189, filed on Sep. 30, 2024, of which entire content is incorporated herein by reference into the present application.

### TECHNICAL FILED

The present the present disclosure relates to an element chip production method and a bonded body production method.

### BACKGROUND

Conventionally, a technique of producing a plurality of element chips by plasma-dicing a substrate has been known (e.g., Japanese Laid-Open Patent Publication No. 2005-191039). The element chip production method of Japanese Laid-Open Patent Publication No. 2005-191039 includes a step of preparing a substrate including a plurality of element regions and a division region defining the element regions, a step of forming a mask layer on the upper surface of the substrate, a step of removing a part of the mask layer corresponding to the division region by laser beam irradiation, and a step of obtaining a plurality of element chips corresponding to the element regions by exposing the division region of the substrate to plasma.

In recent years, the development of a so-called direct bonding technique for directly bonding the element chip surfaces or the element chip surfaces and the substrate surface has been advanced. While the direct bonding is advantageous in that the bonding distance can be reduced, it is required that the surfaces of the element chips and the like be highly flat.

### SUMMARY

One aspect of the present disclosure relates to an element chip production method. The production method includes: a preparation step of preparing a substrate having a plurality of element regions and a division region defining the element regions, the substrate having a first principal surface and a second principal surface and including a first layer being a semiconductor layer and a second layer formed on a first principal surface side of the first layer and including an insulator; a planarization step of planarizing an upper surface of the second layer by polishing the first principal surface side of the substrate; a first protective layer formation step of forming, on the upper surface of the second layer, a first protective layer having a first opening from which the division region is exposed; a first groove formation step of forming a first groove having a first groove width in the division region by performing etching on a part of the second layer exposed from the first opening; a supporting step of supporting the second principal surface of the substrate using a support member; a second protective layer formation step of forming a second protective layer on a surface of the second layer; a laser grooving step of forming a second groove inside the first groove in the division region by irradiating inside of the first groove with a laser beam from the first principal surface side, the second groove having a second groove width smaller than the first groove width, the second groove penetrating the second protective layer and the second layer and reaching the first layer; and a dicing step of forming a plurality of element chips each having one of the element regions and a recess at an outer edge on the first principal surface side by dividing the substrate in the second groove in a state in which the second principal surface is supported by the support member.

Another aspect of the present disclosure relates to a bonded body production method. The production method includes: an element chip preparation step of preparing element chips; a second substrate preparation step of preparing a second substrate; and a bonding step of bonding one of the element chips to the second substrate, wherein the element chip preparation step includes; a preparation step of preparing a first substrate having a plurality of element regions and a division region defining the element regions, the first substrate having a first principal surface and a second principal surface and including a first layer being a semiconductor layer and a second layer formed on a first principal surface side of the first layer and including an insulator; a planarization step of planarizing an upper surface of the second layer by polishing the first principal surface side of the first substrate; a first protective layer formation step of forming, on the upper surface of the second layer, a first protective layer having a first opening from which the division region is exposed; a first groove formation step of forming a first groove having a first groove width in the division region by performing etching on a part of the second layer exposed from the first opening; a supporting step of supporting the second principal surface of the first substrate using a support member; a second protective layer formation step of forming a second protective layer on a surface of the second layer; a laser grooving step of forming a second groove inside the first groove in the division region by irradiating inside of the first groove with a laser beam from the first principal surface side, the second groove having a second groove width smaller than the first groove width, the second groove penetrating the second protective layer and the second layer and reaching the first layer; and a dicing step of forming a plurality of element chips each having one of the element regions and a recess at an outer edge on the first principal surface side by dividing the first substrate in the second groove in a state in which the second principal surface is supported by the support member, and in the bonding step, the first principal surface side of the element chips is brought into close contact with the second substrate and bonded thereto.

### BRIEF DESCRIPTION OF THE DRAWINGS

FIG. 1 is a cross-sectional view explaining a preparation step in a first embodiment, which illustrates an example of a first substrate.

FIG. 2 is a cross-sectional view explaining a planarization step in the first embodiment, in which the upper surface of a second layer is planarized.

FIG. 3 is a cross-sectional view explaining a first protective layer formation step in the first embodiment, in which a first protective layer is formed on the upper surface of the second layer.

FIG. 4 is a cross-sectional view explaining a first groove formation step in the first embodiment, in which a first groove is formed in a division region.

FIG. 5 is a cross-sectional view explaining a first protective layer removal step in the first embodiment, in which the first protective layer is removed.

FIG. 6 is a cross-sectional view explaining a thinning step in the first embodiment, in which the first substrate is thinned.

FIG. 7 is a cross-sectional view explaining a supporting step in the first embodiment, in which the first substrate is supported by a support member.

FIG. 8 is a cross-sectional view explaining a second protective layer formation step in the first embodiment, in which a second protective layer is formed on the surface of the second layer.

FIG. 9 is a cross-sectional view explaining a laser grooving step in the first embodiment, in which a second groove is formed inside the first groove.

FIG. 10 is a cross-sectional view explaining a dicing step in the first embodiment, illustrating a plurality of element chips.

FIG. 11 is a cross-sectional view explaining a second protective layer removal step in the first embodiment, in which the second protective layer is removed.

FIG. 12 is a cross-sectional view explaining a second substrate preparation step and a bonding step in the first embodiment, in which an element chip is bonded to a second substrate.

FIG. 13 is a schematic diagram illustrating an example of a plasma processing apparatus.

FIG. 14 is a cross-sectional view explaining the first protective layer formation step in a second embodiment, in which the first protective layer is formed on the upper surface of the second layer.

FIG. 15 is a cross-sectional view explaining the first groove formation step in the second embodiment, in which the first groove is formed in the division region.

FIG. 16 is a cross-sectional view explaining the first protective layer removal step in the second embodiment, in which the first protective layer is removed.

FIG. 17 is a cross-sectional view explaining the planarization step in the second embodiment, in which the upper surface of the second layer is planarized.

FIG. 18 is a cross-sectional view explaining the preparation step in a sixth embodiment, which illustrates another example of the first substrate.

FIG. 19 is a cross-sectional view explaining the first groove formation step in the sixth embodiment, in which the first groove is formed in the division region.

FIG. 20 is a cross-sectional view of a plurality of element chips obtained in the sixth embodiment.

### DETAILED DESCRIPTION

The following describes, using examples, embodiments of an element chip production method and a bonded body production method according to the present disclosure. However, the present disclosure is not limited to the examples described below. In the following description, specific numerical values and materials may be exemplified in some cases, but other numerical values and other materials may be adopted as long as the effects of the present disclosure can be obtained.

### (Element Chip Production Method)

An element chip production method according to the present disclosure is a method for obtaining a plurality of element chips by singulating a substrate. The element chip production method according to the present disclosure includes a preparation step, a planarization step, a first protective layer formation step, a first groove formation step, a supporting step, a second protective layer formation step, a laser grooving step, and a dicing step. Note that the execution order of the steps is not limited to the sequence of description. However, typically, the second groove formation step is performed after the first groove formation step, the laser grooving step is performed after the second protective layer formation step, and the dicing step is performed after the laser grooving step.

In the preparation step, a substrate having a first principal surface and a second principal surface is prepared. The substrate includes a first layer being a semiconductor layer, and a second layer formed on the first principal surface side of the first layer and including an insulator. The substrate has a plurality of element regions and a division region defining the element regions. The first layer and the second layer may be in contact with each other. The semiconductor material contained in the first layer is not particularly limited, and may be, for example, Si, SiC, GaN, or GaAs. For example, the second layer may include an insulating film of, for example, SiO₂, SiN, or SiCN, and may contain a metal such as Cu, Al. The shape of the element regions is not particularly limited, and may be, for example, rectangular, polygonal, or circular. The width of the division region is also not particularly limited and can be appropriately set according to the purpose. The thickness of the second layer may be, for example, 3 μm or more and 20 μm or less, or may be 8 μm or more and 18 μm or less.

In the planarization step, the upper surface of the second layer is planarized by polishing the first principal surface side of the substrate. In the planarization step, the upper surface of the second layer may be planarized by chemical mechanical polishing (CMP), for example. The upper surface portion (or the outermost surface portion) of the second layer may contain SiO₂, SiON (silicon oxynitride), or SiCN (silicon carbonitride).

In the first protective layer formation step, a first protective layer having a first opening from which the division region is exposed is formed on the upper surface of the second layer. The first protective layer may contain a water-soluble or water-insoluble resin material. Examples of the water-insoluble resin material can include photoresist materials. The first protective layer may or may not be removed before the second protective layer formation step. The first protective layer is preferably formed of photoresist. The cross-sectional shape of the edge of the first opening of the first protective layer may be a forward tapered shape or a round shape.

In the first groove formation step, a first groove having a first groove width is formed in the division region by etching a part of the second layer exposed from the first opening. No particular limitations are placed on the etching method, and plasma etching or sputter etching can be used, for example. The etching may be performed under the condition that no substantial protrusions (or burrs) are formed at the opening edge of the first groove. The first groove width may be substantially the same as the opening width of the first opening. The depth of the first groove may be 0.2 μm or more and 2 μm or less, for example. Further, when the edge of the first opening of the first protective layer is formed into a forward tapered shape or a round shape in cross section in the first protective layer formation step, protrusions (or burrs) are hardly formed at the opening edge of the first groove when sputter etching is performed in the first groove formation step.

In the supporting step, the second principal surface of the substrate is supported using a support member. The support member may include an annular frame and a holding sheet that is mounted on the frame and to which the substrate is attached.

In the second protective layer formation step, a second protective layer is formed on the surface of the second layer where the first groove is formed. The second protective layer may contain a water-soluble or water-insoluble resin material. Example of the water-insoluble resin material includes photoresist materials. Of all, the second protective layer is preferably formed of a water-soluble resin. The “surface” of the second layer includes the upper surface of the second layer and a bottom surface and a side wall surface of the first groove. When the first protective layer remains on the upper surface of the second layer, formation of the second protective layer on the surface of the second layer includes formation of the second protective layer on the surface of the first protective layer. Formation of the second protective layer may be performed using a spin coater or a spray coater. When a spin coater is used in formation of the second protective layer, the depth of the first groove formed in the first groove formation step is preferably 2 μm or less in order to make the coating property of the second protective layer with respect to the surface of the second layer favorable.

In the laser grooving step, in the division region, a second groove having a second groove width smaller than the first groove width is formed inside the first groove by removing parts of the second protective layer and the second layer through irradiation of the inside of the first groove with a laser beam from the first principal surface side. The second groove penetrates the second protective layer and the second layer and reaches the first layer. A step corresponding to the first groove is formed between the thus formed second groove and the upper surface of the second layer. Due to the presence of the step, the later-described recess can be formed in the dicing step. The laser beam may be an ultra-short pulse laser beam of the order of picoseconds or femtoseconds. However, in terms of production cost, a short pulse laser beam of the order of nano is preferable. The laser beam is absorbed in the second protective layer and the second layer but may not be absorbed in the first layer.

In the dicing step, a plurality of element chips each having an element region and a recess at the outer edge on the first principal surface side is formed by dividing the substrate in the second groove in a state in which the second principal surface is supported by the support member. In each of the element chips obtained in this way, minute protrusions having sizes ranging from tens to hundreds of nanometers can be formed at the edge, more specifically, at the edge of the bottom surface of the recess. These minute protrusions have been a factor hindering direct bonding. However, in the present disclosure, the minute protrusions do not protrude above the upper surface of the second layer and do not hinder direct bonding because of being formed at the edge of the bottom surface of the recess. Therefore, the depth of the first groove formed in the first groove formation step is preferably 0.2 μm or more.

The planarization step may be performed before the first protective layer formation step. In this case, the upper surface of the second layer can be planarized more easily than in the case in which the planarization step is performed after the first protective layer formation step or the subsequent first groove formation step.

The planarization step may be performed after the first groove formation step. In this case, minute protrusions can be removed in the subsequent planarization step even if the minute protrusions are formed at the opening edge of the first groove in the first groove formation step.

The element chip production method may further include a thinning step of thinning the substrate by grinding the second principal surface side of the substrate after the first groove formation step. In the supporting step, the second principal surface of the substrate, which has been thinned, may be supported using the support member.

The preparation step may include a thinning step of thinning the substrate by grinding the second principal surface side of the substrate. In this case, the thickness of the thinned substrate is preferably 300 μm or more.

The element chip production method may further include a thinning step of thinning the substrate by grinding the second principal surface side of the substrate after the planarization step. In the supporting step, the second principal surface of the thinned substrate may be supported using the support member. The thinning step may be performed after the planarization step and before the first protective layer formation step.

A part of the second layer located in the division region may include a metal pattern exposed on the surface. Second layer etching in the first groove formation step may include sputter etching of etching the insulator and the metal pattern. In the thickness direction of the substrate, the maximum distance between the bottom surface of the first groove and the second principal surface may be smaller than the distance between the upper surface of the second layer in the element regions and the second principal surface. Even if minute protrusions are formed at the edge of the bottom surface of the recess in the laser grooving step, establishment of such a relative magnitudes of the distances therebetween can prevent the minute protrusions from hindering direct bonding. The metal pattern may be a test element group (TEG). The maximum distance between the bottom surface of the first groove and the second principal surface may be a distance between the surface of the metal pattern after sputter etching and the second principal surface.

The dicing step may include a plasma dicing step of dividing the substrate by etching the first layer through plasma exposure of the second groove. In this plasma etching, at least the second protective layer may be used as a mask. A Bosch process may be employed in the first layer etching.

The dicing step may include a laser irradiation step of dividing the substrate by irradiating the second groove with a laser beam.

The dicing step may include a blade dicing step of dividing the substrate in the second groove using a blade thinner than the second groove width.

### (Bonded Body Production Method)

The bonded body production method according to the present disclosure is a method for producing a bonded body by bonding to a second substrate an element chip obtained by singulating a substrate. The bonded body production method according to the present disclosure includes an element chip preparation step, a second substrate preparation step, and a bonding step.

The element chip preparation step includes a preparation step, a planarization step, a first protective layer formation step, a first groove formation step, a supporting step, a second protective layer formation step, a laser grooving step, and a dicing step, similarly to the element chip production method according to the present disclosure. The respective steps may be performed in the same manner as the steps in the element chip production method, wherein the term “substrate” in the element chip production method according to the present disclosure is replaced with the term “first substrate”. The surface of each element chip may be subjected to a hydrophilization treatment through surface activation using plasma and subsequent water washing.

In the second substrate preparation step, a second substrate is prepared. The surface of the second substrate may have a region constituted of SiO₂, SiON, or SiCN and a region constituted of a metal such as Cu or Al. The surface of the second substrate may be subjected to a hydrophilization treatment through surface activation using plasma and subsequent water washing.

In the bonding step, the element chip is bonded to the second substrate. In the bonding step, the first principal surface side of the element chip is brought into close contact with the second substrate and bonded thereto. The bonding step may be performed by direct bonding (e.g., hybrid bonding). Since there are no minute protrusions on the first principal surface of the element chip, the bonding can be performed favorably.

According to the present disclosure, the formation of the first groove and the second groove can achieve production of element chips suitable for direct bonding as described above. Furthermore, according to the present disclosure, a bonded body including such an element chip can be produced by direct bonding.

The following describes examples of the element chip production method and the bonded body production method according to the present disclosure in detail with reference to the accompanying drawings. The above-described steps can be applied to the steps of the element chip production method and the steps of the bonded body production method described below as examples. The steps of the element chip production method and the steps of the bonded body production method described below as examples can be altered based on the description described above. Further, the matters described below may be applied to the above-described embodiments. Among the steps of the exemplary element chip production method and the steps of the exemplary bonded body production method described below, any step that is not essential to the element chip production method or the bonded body production method according to the present disclosure may be omitted. It should be noted that the drawings indicated below are schematic and do not accurately reflect the shape or number of actual members.

### EMBODIMENT 1

The following describes a first embodiment of the present disclosure. A bonded body production method of the present embodiment is a method for producing a bonded body by bonding to a second substrate an element chip obtained by singulating a first substrate. The bonded body production method includes an element chip preparation step of preparing an element chip 10, a second substrate preparation step of preparing a second substrate 50, and a bonding step of bonding the element chip 10 to the second substrate 50.

The element chip preparation step is a step that can correspond to the element chip production method according to the present disclosure, and includes a preparation step, a planarization step, a first protection layer formation step, a first groove formation step, a first protection layer removal step, a thinning step, a supporting step, a second protection layer formation step, a laser grooving step, a dicing step, and a second protection layer removal step.

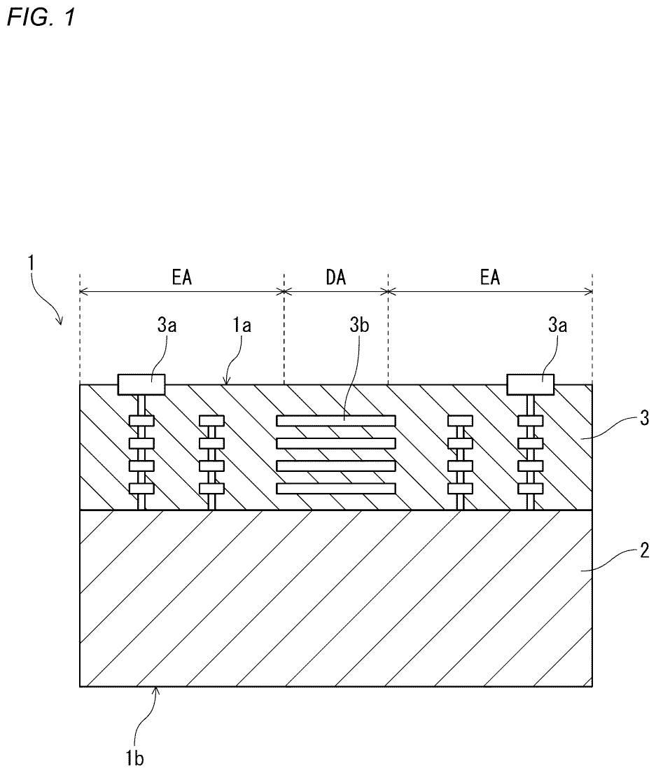

In the preparation step, a first substrate 1 having a first principal surface 1a and a second principal surface 1b is prepared as illustrated in FIG. 1. The first substrate 1 includes a first layer 2 being a semiconductor layer, and a second layer 3 formed on the first principal surface 1a side of the first layer 2 and including an insulator. The first substrate 1 has a plurality of element regions EA and a division region DA defining the element regions EA. The upper surface (outermost surface) portion of the second layer 3 in the present embodiment contains SiO₂ but is not limited thereto. At least one metal electrode 3a is provided in a part of the second layer 3 corresponding to each of the element regions EA. At least one metal electrode 3b is provided in a part of the second layer 3 corresponding to the division region DA. For example, a part of the metal electrode 3a corresponding to the element region EA protrudes from the upper surface of the second layer 3.

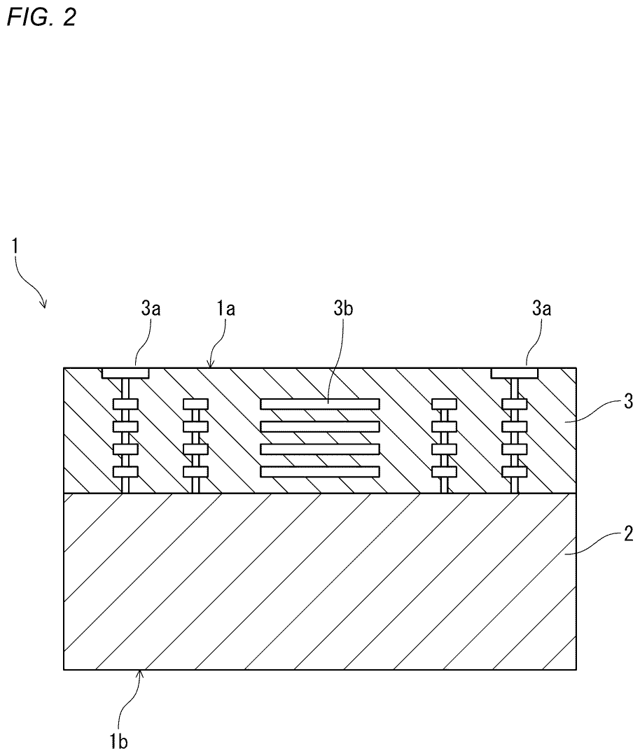

In the planarization step, the upper surface of the second layer 3 is planarized by polishing the first principal surface 1a side of the first substrate 1 as illustrated in FIG. 2. The upper surface of the second layer 3 is planarized by CMP in the present embodiment but is not limited thereto. The planarization step in the present embodiment is performed before the first protective layer formation step.

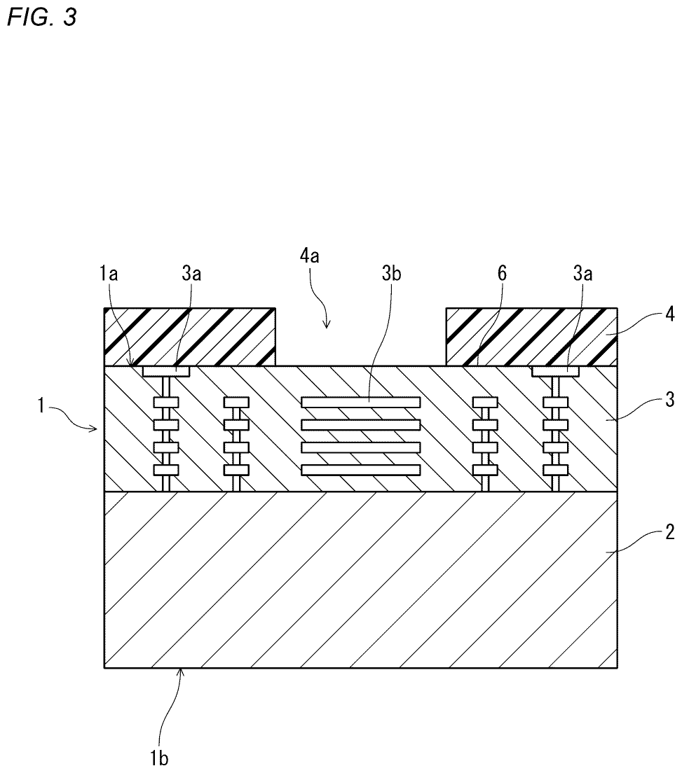

In the first protective layer formation step, a first protective layer 4 is formed on the planarized upper surface of the second layer 3 as illustrated in FIG. 3. The first protective layer 4 has a first opening 4a from which the division region DA is exposed. The first protective layer 4 having the first opening 4a such as above can be formed by, for example, forming a protective layer on the entire upper surface of the second layer 3, followed by removing a part of the protective layer corresponding to the division region DA. The first protective layer 4 in the present embodiment contains photoresist but the present disclosure is not limited thereto.

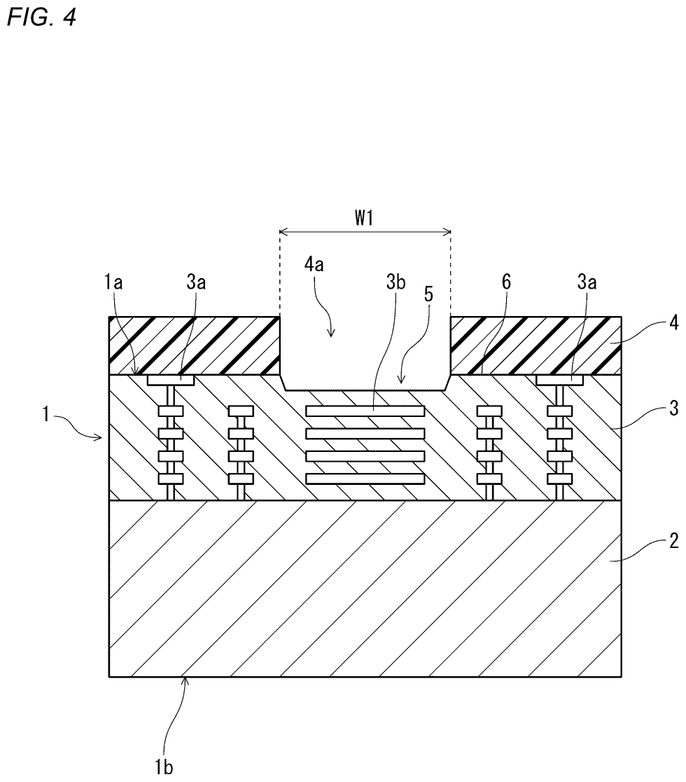

In the first groove formation step, a first groove 5 having a first groove width W1 is formed in the division region DA by etching a part of the second layer 3 exposed from the first opening 4a as illustrated in FIG. 4. The etching may be etching using plasma.

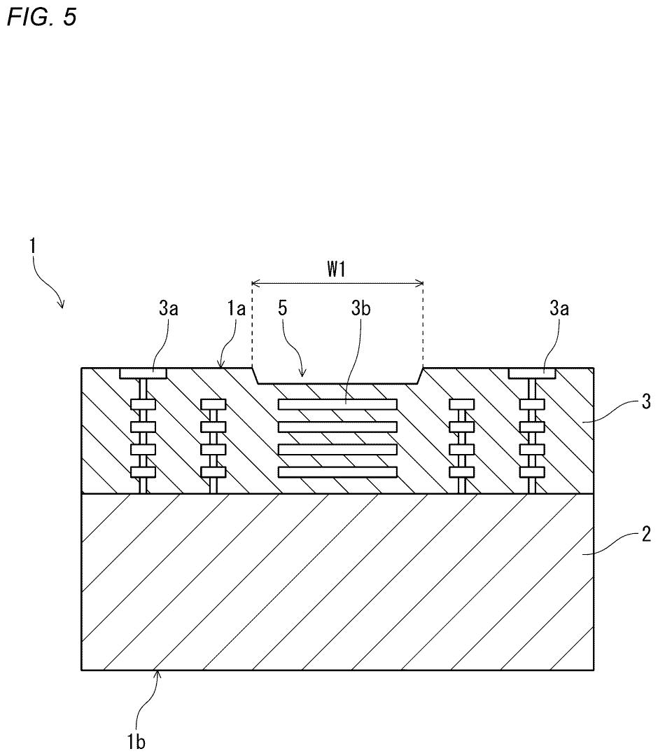

In the first protective layer removal step, the first protective layer 4 is removed as illustrated in FIG. 5. The first protective layer 4 of the present embodiment, which contains, for example, photoresist as described above, can be removed by washing with an organic solvent, ashing with oxygen plasma, or the like. Note that the second protective layer 6 may be formed on the first protective layer 4 in the later-described second protective layer formation step without removing the first protective layer 4 in this step.

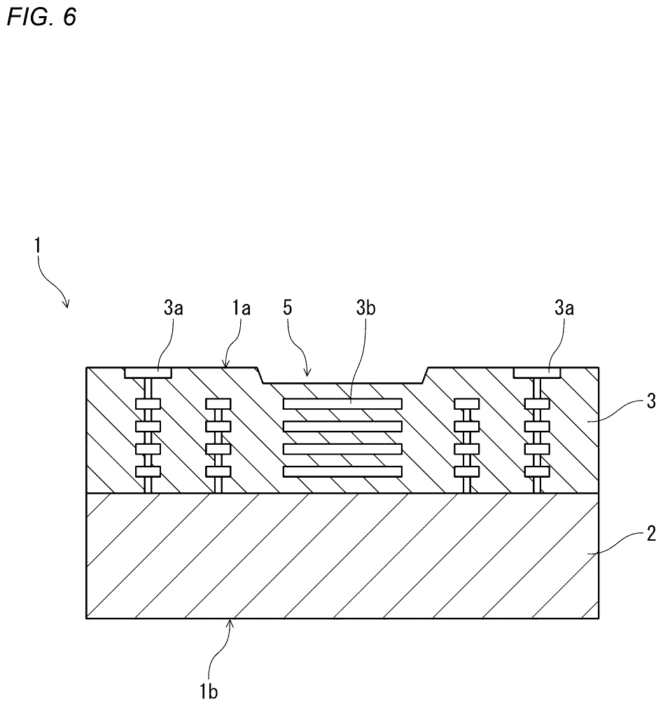

In the thinning step, the first substrate 1 is thinned by grinding the second principal surface 1b side of the first substrate 1 as illustrated in FIG. 6. The grinding may be performed using, for example, a back grinder. The thinning step in the present embodiment is performed after the first groove formation step.

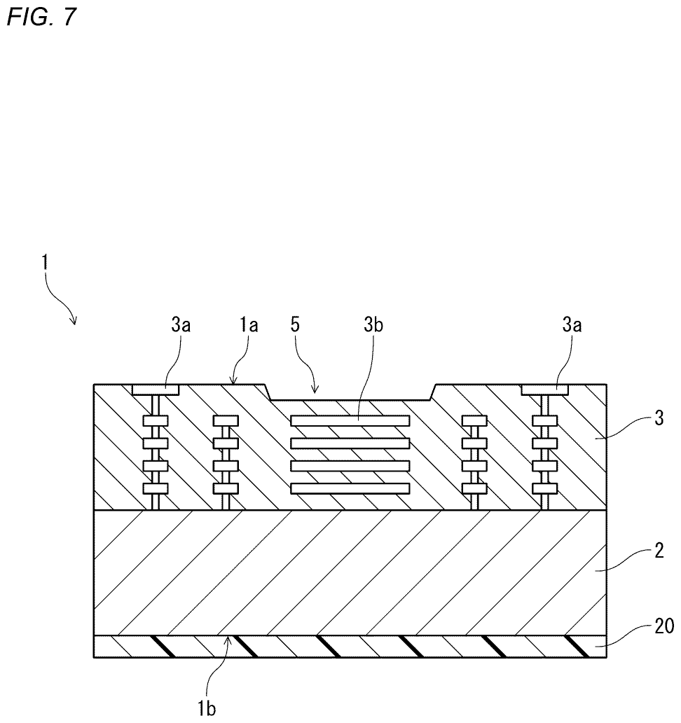

In the supporting step, the second principal surface 1b of the first substrate 1, which has been thinned, is supported using a support member 20 (e.g., a resin-made holding sheet) as illustrated in FIG. 7.

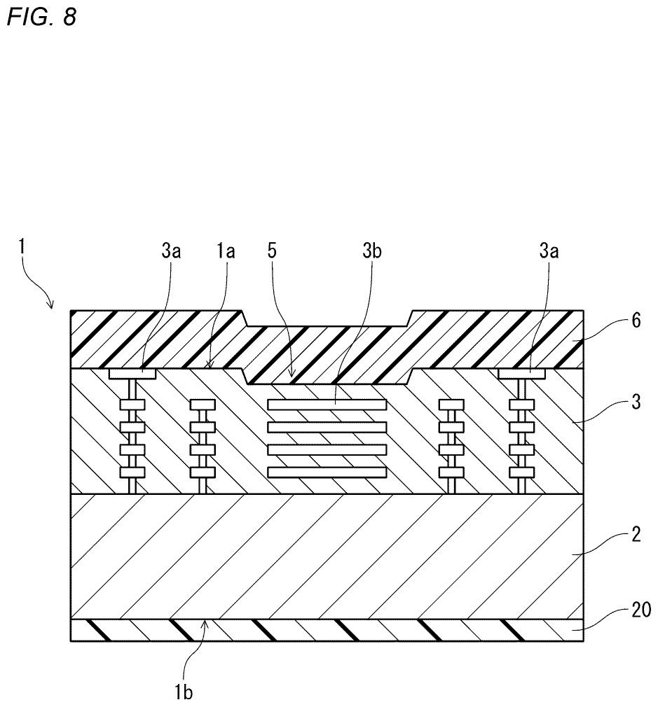

In the second protective layer formation step, a second protective layer 6 is formed on the surface of the second layer 3 as illustrated in FIG. 8. The second protective layer 6 in the present embodiment contains a water-soluble resin but the present disclosure is not limited thereto.

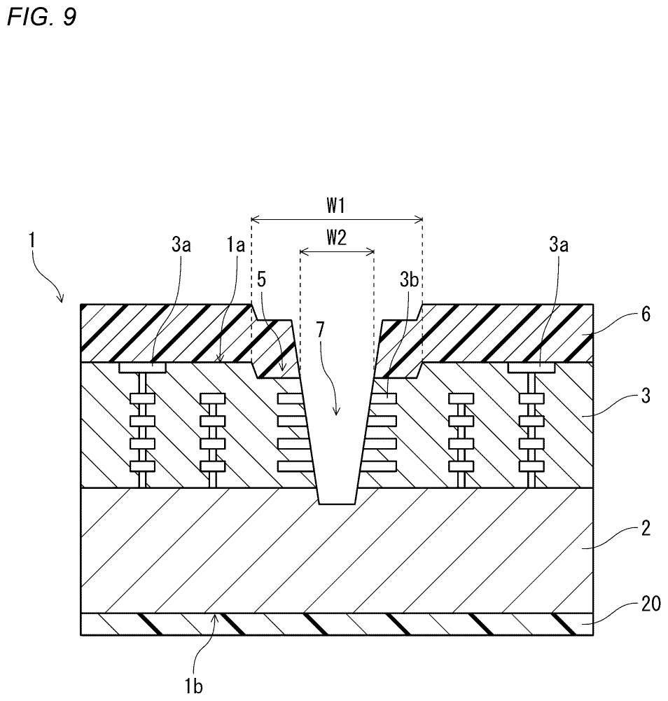

In the laser grooving step, in the division region DA, a second groove 7 having a second groove width W2 smaller than the first groove width W1 is formed inside the first groove 5 by removing parts of the second protective layer 6 and the second layer 3 through irradiation of the inside of the first groove 5 with a laser beam (not shown) from the first principal surface 1a side, as illustrated in FIG. 9. The second groove 7 penetrates the second protective layer 6 and the second layer 3 and reaches the first layer 2. The bottom surface of the second groove 7 is located on the upper surface of or inside the first layer 2.

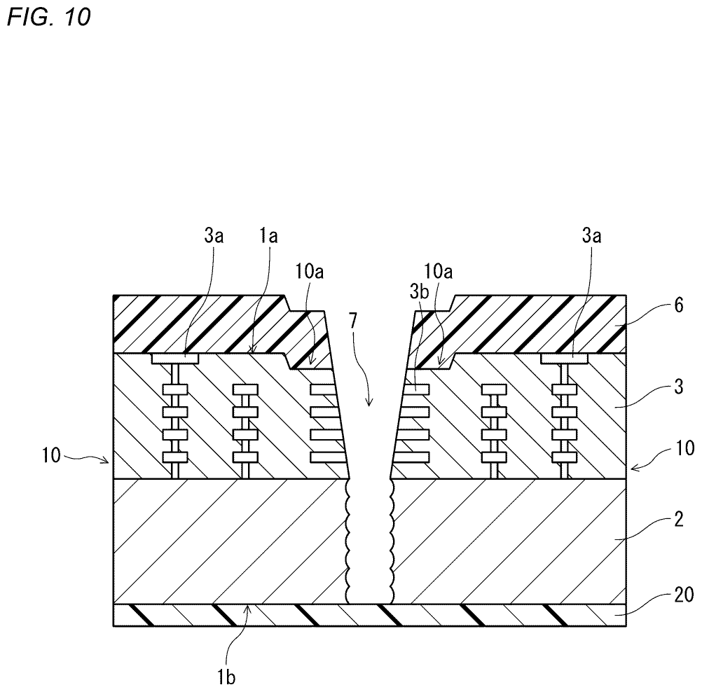

In the dicing step, a plurality of element chips 10 each including an element region EA and a recess 10a at the outer edge on the first principal surface 1a side is formed by dividing the first substrate 1 in the second groove 7 in a state in which the second principal surface 1b is supported by the support member 20 as illustrated in FIG. 10. The dicing step in the present embodiment includes a plasma dicing step of dividing the first substrate 1 by etching the first layer 2 through plasma exposure of the second groove 7, but the present disclosure is not limited thereto. For example, the dicing step may include a laser irradiation step of dividing the first substrate 1 by irradiating the second groove 7 with a laser beam, or a blade dicing step of dividing the first substrate 1 in the second groove 7 using a blade (not illustrated) thinner than the second groove width W2.

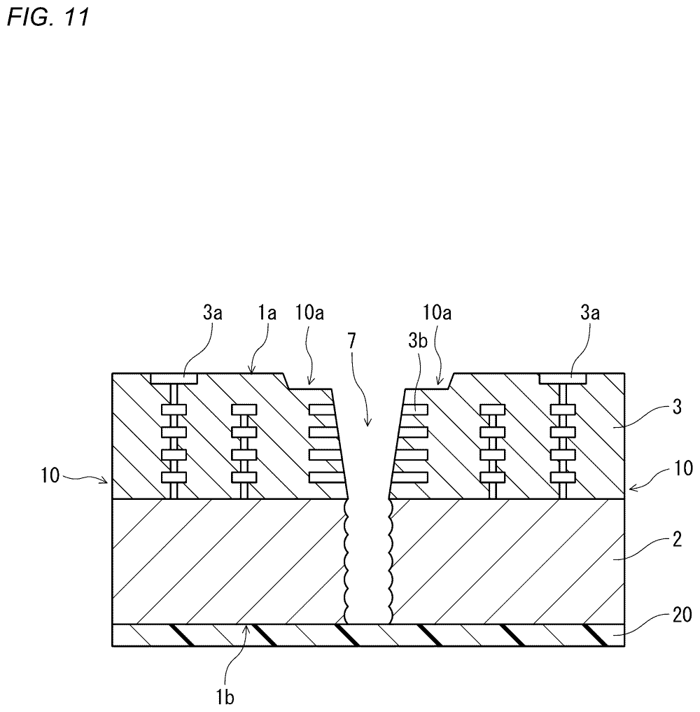

In the second protective layer removal step, the second protective layer 6 is removed after the dicing step as illustrated in FIG. 11. The second protective layer 6 in the present embodiment, which contains a water-soluble resin as described above, can be removed by washing with a cleaning solution containing water (e.g., water).

The second substrate 50 prepared in the second substrate preparation step may include a semiconductor layer 51 and a wiring layer 52 provided on the upper surface of the semiconductor layer 51 and including an insulator. The insulator (e.g., SiO₂) and a metal electrode 52a are exposed on the outermost surface of the wiring layer 52.

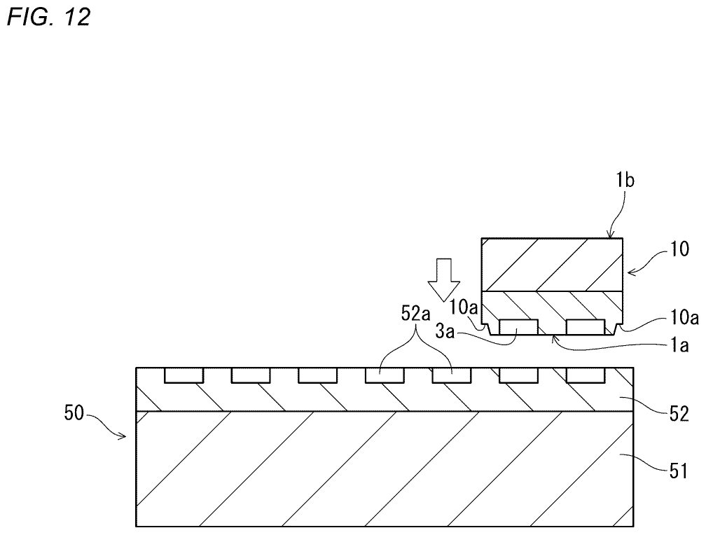

In the bonding step, the first principal surface 1a side of an element chip 10 prepared in the element chip preparation step is brought into close contact with the second substrate 50 prepared in the second substrate preparation step and bonded thereto as illustrated in FIG. 12. In doing so, even if minute protrusions (or burrs) are present at the edge of the bottom surface of the recess 10a, the minute protrusions such as above do not hit the surface of the second substrate 50 because the element chip 10 has the recess 10a at the outer edge on the first principal surface 1a side. As a result, the bonding can be performed favorably. Note that, prior to the bonding step, both the first principal surface 1a of the element chip 10 and the surface of the second substrate 50 are preferably hydrophilized by a surface activation treatment using plasma and a subsequent water washing.

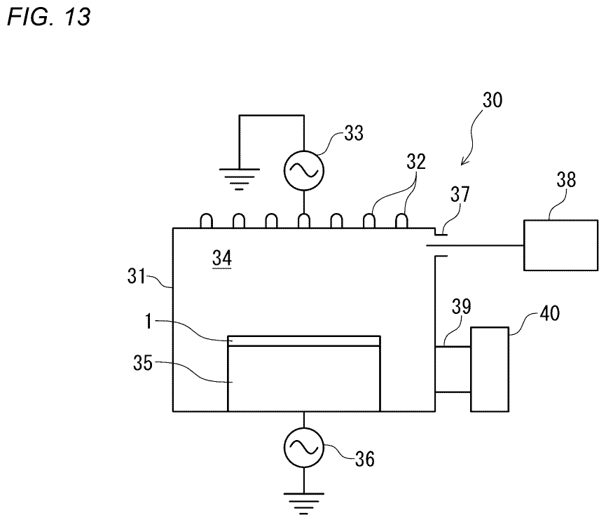

In the first groove formation step and the dicing step, a plasma processing apparatus 30 (a plasma etching apparatus 30) illustrated in FIG. 13 may be used. The plasma processing apparatus 30 includes a chamber 31 provided with a dielectric window at the top and defining a processing room 34, an antenna 32 as an upper electrode provided on the upper side of the chamber 31, a first high-frequency power supply 33 electrically connected to the antenna 32, a stage 35 as a lower electrode that is provided on the bottom side of the processing room 34 and on which the first substrate 1 is to be placed, and a second high-frequency power supply 36 electrically connected to the stage 35. A gas inlet 37 formed in the chamber 31 is fluidly connected to a source gas supply 38. An exhaust port 39 formed in the chamber 31 is fluidly connected to a vacuum exhaust section 40 including a vacuum pump.

In the plasma processing apparatus 30 illustrated in FIG. 13, after the first substrate 1 is placed on the stage 35, the processing room 34 is reduced in pressure by the vacuum exhaust section 40, while a source gas is supplied from the source gas supply 38 to the processing room 34. Thereafter, high-frequency power is supplied from the first high-frequency power supply 33 to the antenna 32 to generate plasma in the processing room 34 and irradiate the first substrate 1. A part of the first layer 2 exposed on the bottom of the second groove 7 can be removed by physicochemical action of radicals and ions in the plasma. By supplying the high-frequency power from the second high-frequency power supply 36 to the stage 35, the collision speed of radicals and ions relative to the first substrate 1 can be controlled.

The processing conditions in the first groove formation step are as follows, for example. As the process gases, 20 sccm or more and 80 sccm or less of CF₄ and 150 sccm or more and 300 sccm or less of Ar are supplied to the chamber 31. The pressure in the chamber 31 is 0.4 Pa or more and 1.0 Pa or less. The high-frequency power applied to the antenna 32 is 1000 W or more and 2000 W or less. The high-frequency power applied to the stage 35 is 500 W or more and 1500 W or less. The processing time is 20 seconds or longer and 360 seconds or shorter.

As the process gas, a mixed gas of CF₄ and Ar is preferably used. By using a mixed gas of CF₄ and Ar, a decrease in the etch rate of the metal such as Cu relative to the etch rate of the insulating film such as SiO₂ can be suppressed. Therefore, the first groove 5 can be easily formed even in a case in which a part of the second layer 3 located in the division region DA includes a metal pattern exposed on the surface. In addition, use of a mixed gas of CF₄ and Ar can achieve formation of the first groove 5 with the first protective layer 4 receding under control of the ratio between the etch rate of the first protective layer 4 and the etch rate of the second layer 3. Thus, adhesion of the reaction product to the etched side surface can be suppressed.

In the examples of the processing conditions, CF₄ is used as a fluorine-containing gas. However, SF₆ or C4F₈ may be used. Further, an Ar gas containing no fluorine-containing gases may be used as the process gas. In a case in which a part of the second layer 3 located in the division region DA includes a metal pattern exposed on the surface, the process gas preferably does not contain O₂ in order to prevent metal pattern etching from being inhibited.

The dicing step may be performed through repetition of a protective film deposition step, a protective film removal step, and a substrate etching step multiple times. The processing conditions in the protective film deposition step are as follows, for example. As a process gas, 150 sccm or more and 600 sccm or less of C₄F₈ is supplied to the chamber 31. The pressure in the chamber 31 is 8 Pa or more and 16 Pa or less. The high-frequency power applied to the antenna 32 is 2000 W or more and 8000 W or less. The high-frequency power applied to the stage 35 is 15 W or more and 80 W or less. The processing time is 1 second or longer and 5 seconds or shorter. The processing conditions in the protective film removal step are as follows, for example. As a process gas, 200 sccm or more and 800 sccm or less of SF₆ is supplied to the chamber 31. The pressure in the chamber 31 is 4 Pa or more and 12 Pa or less. The high-frequency power applied to the antenna 32 is 2000 W or more and 8000 W or less. The high-frequency power applied to the stage 35 is 150 W re more and 600 W or less. The processing time is 1 second or longer and 5 seconds or shorter. The processing conditions in the substrate etching step are as follows, for example. As a process gas, 200 sccm or more and 800 sccm or less of SF₆ is supplied to the chamber 31. The pressure in the chamber 31 is 20 Pa or more and 40 Pa or less. The high-frequency power applied to the antenna 32 is 2500 W or more and 10,000 W or less. The high-frequency power applied to the stage 35 is 20 W or more and 100 W or less. The processing time is 2 seconds or longer and 10 seconds or shorter. The number of repetitions of the protective film deposition step, the protective film removal step, and the substrate etching step is 20 times or more and 50 times or less, for example.

### SECOND EMBODIMENT

The following describes a second embodiment of the present disclosure. A bonded body production method of the present embodiment is different from that in the first embodiment in that the planarization step is performed after the first groove formation step. Hereinafter, differences from the first embodiment will be mainly described.

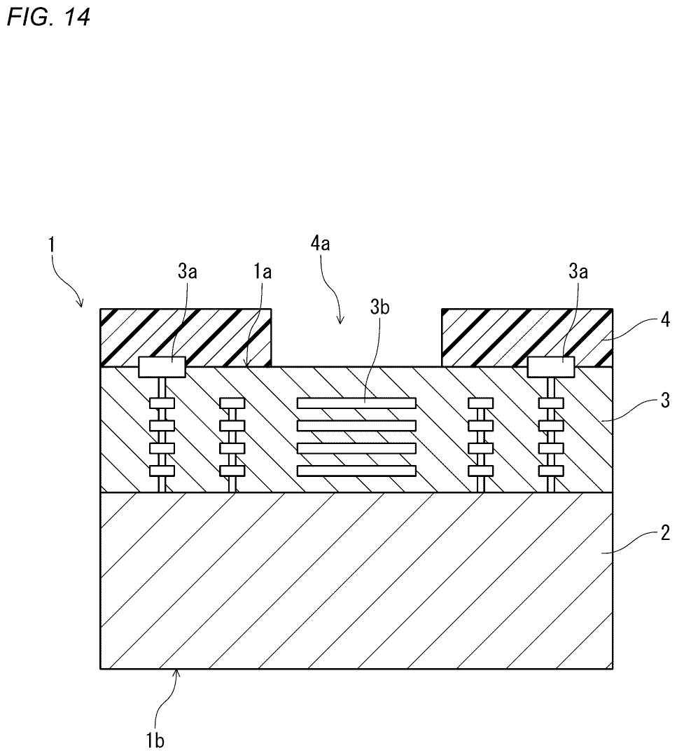

As illustrated in FIG. 14, in the first protective layer formation step of the present embodiment, the first protective layer 4 having the first opening 4a from which the division region DA is exposed is formed on the upper surface of the second layer 3 of the first substrate 1 prepared in the preparation step.

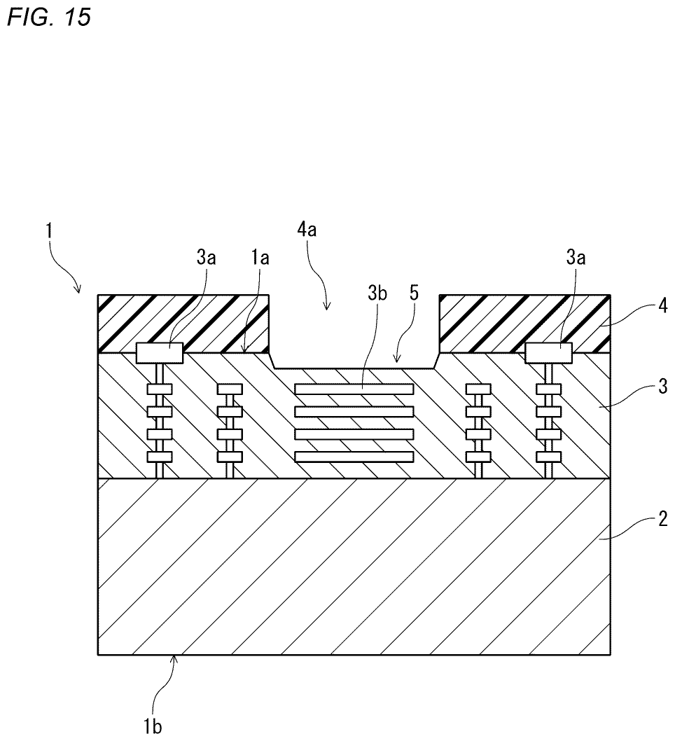

Thereafter, the first groove formation step of forming the first groove 5 having the first groove width W1 in the division region DA is performed by etching a part of the second layer 3 exposed from the first opening 4a as illustrated in FIG. 15.

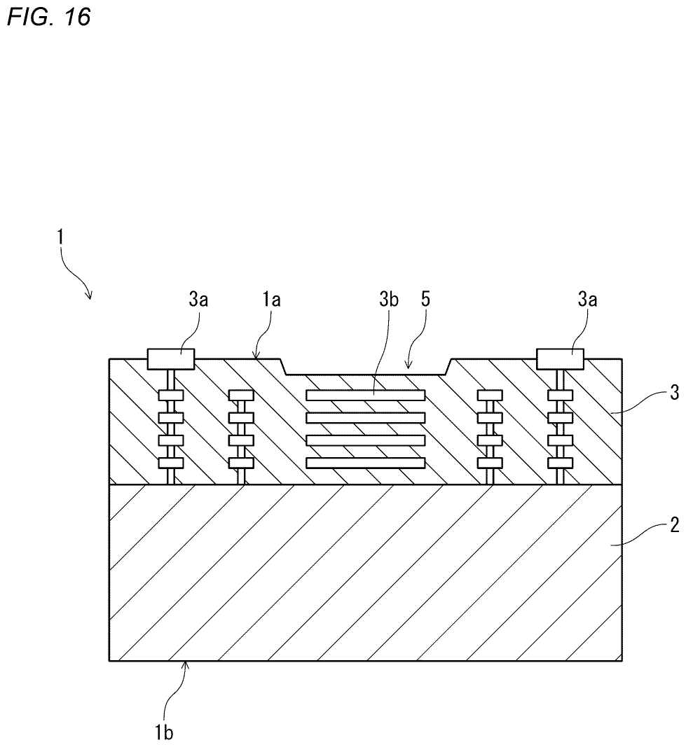

Subsequently, the first protective layer removal step of removing the first protective layer 4 is performed as illustrated in FIG. 16.

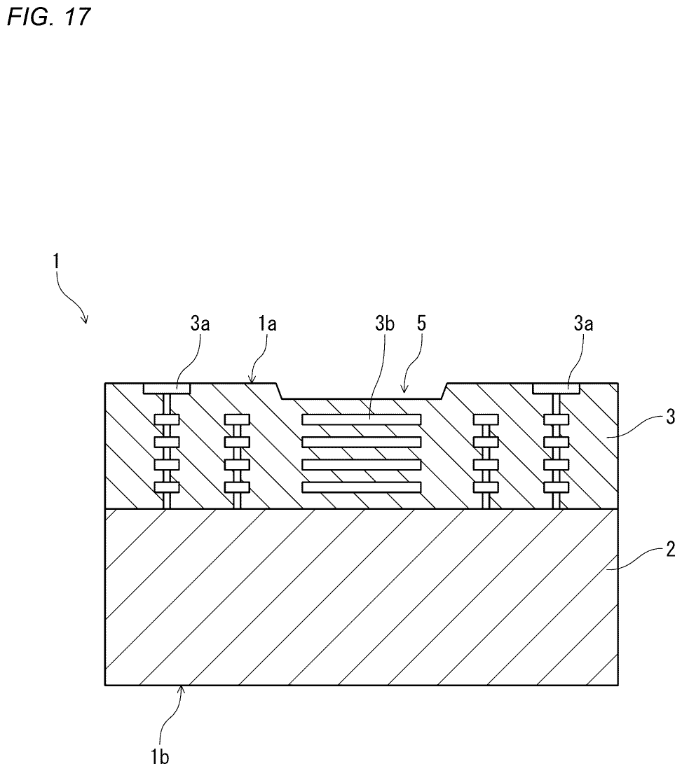

Then, the planarization step of planarizing the upper surface of the second layer 3 is performed by polishing the first principal surface 1a side of the first substrate 1 having the first groove 5 as illustrated in FIG. 17. Thus, even if minute protrusions (or burrs) are formed at the opening edge of the first groove 5, the minute protrusions can be removed in the planarization step.

Thereafter, the thinning step, the supporting step, the second protective layer formation step, the laser grooving step, the dicing step, and the second protective layer removal step are performed in the same manner as in the first embodiment. As a result, a plurality of element chips 10 each having the recess 10a can be obtained.

### THIRD EMBODIMENT

The following describes a third embodiment of the present disclosure. A bonded body production method of the present embodiment is different from that of the first embodiment in that the thinning step is included in the preparation step. That is, although not illustrated, the preparation step of the present embodiment includes a thinning step of thinning the first substrate 1 by grinding the second principal surface 1b side of the first substrate 1. Each of the subsequent steps can be performed in the same manner as in the first embodiment except the thinning step.

### FOURTH EMBODIMENT

The following describes a fourth embodiment of the present disclosure. A bonded body production method of the present embodiment is different from that of the second embodiment in that the thinning step is included in the preparation step. That is, although not illustrated, the preparation step of the present embodiment includes a thinning step of thinning the first substrate 1 by grinding the second principal surface 1b side of the first substrate 1. Each of the subsequent steps can be performed in the same manner as in the first embodiment except the thinning step.

### FIFTH EMBODIMENT

The following describes a fifth embodiment of the present disclosure. A bonded body production method of the present embodiment is different from that of the first embodiment in that the thinning step is performed after the planarization step and before the first protective layer formation step. That is, although not illustrated, the element chip preparation step of the present embodiment further includes a thinning step of thinning the first substrate 1 by grinding the second principal surface 1b side of the first substrate 1 after the planarization step and before the first protective layer formation step. In the supporting step, the second principal surface 1b of the thinned first substrate 1 is supported using the support member 20.

### SIXTH EMBODIMENT

The following describes a sixth embodiment of the present disclosure. A bonded body production method of the present embodiment is different from that of the first embodiment in that the first substrate 1 includes a predetermined metal pattern 3c. Hereinafter, differences from the first embodiment will be mainly described.

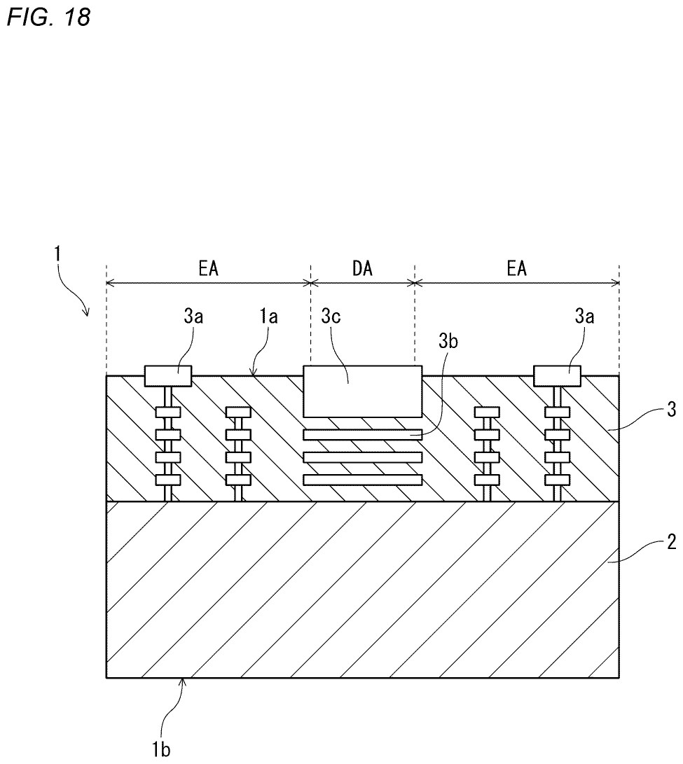

The first substrate 1 prepared in the preparation step in the present embodiment includes a metal pattern 3c that is exposed on the surface of a part of the second layer located in the division region DA as illustrated in FIG. 18. The metal pattern 3c may constitute a TEG.

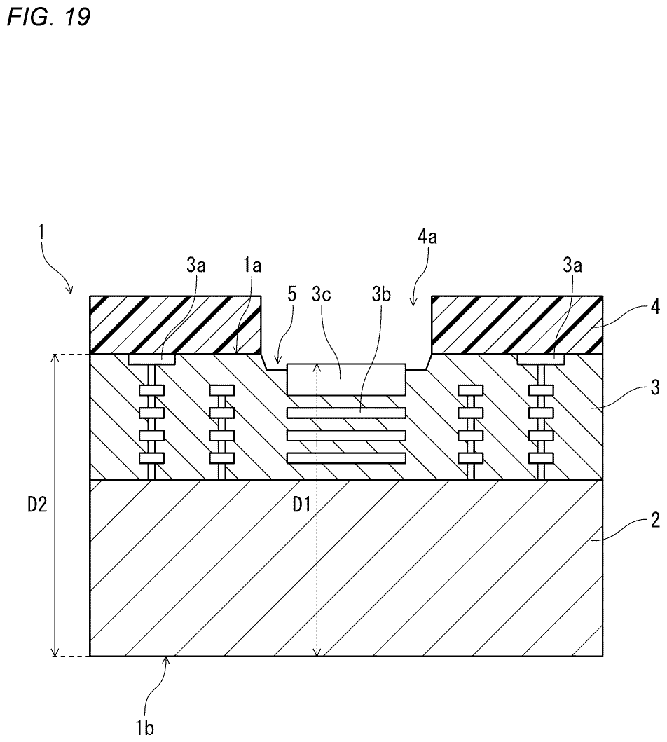

FIG. 19 illustrates a first substrate 1 with the first groove 5 formed in the first groove formation step of the present embodiment. The etching of the second layer 3 in the first groove formation step of the present embodiment includes sputter etching of etching the insulator and the metal pattern 3c included in the second layer 3. It can be seen from FIG. 19 that the metal pattern 3c, which is relatively difficult to etch, protrudes toward the first principal surface 1a more than the insulator, which is relatively easy to etch. In the thickness direction of the first substrate 1 (vertical direction in FIG. 19), the maximum distance between the bottom surface of the first groove 5 and the second principal surface 1b (i.e., a distance D1 between the upper surface of the metal pattern 3c and the second principal surface 1b) is smaller than a distance D2 between a part of the upper surface of the second layer 3 located in the element regions EA and the second principal surface 1b.

In a case in which the etching of the second layer 3 is performed using plasma in the first groove formation step, a mixed gas of CF₄ and Ar is preferably used as the process gas. Use of the mixed gas of CF₄ and Ar can suppress a decrease in the etch rate of the metal such as Cu relative to the etch rate of the insulating film such as SiO₂, and consequently, the protrusion of the metal pattern 3c from the bottom surface of the first groove 5 can be reduced.

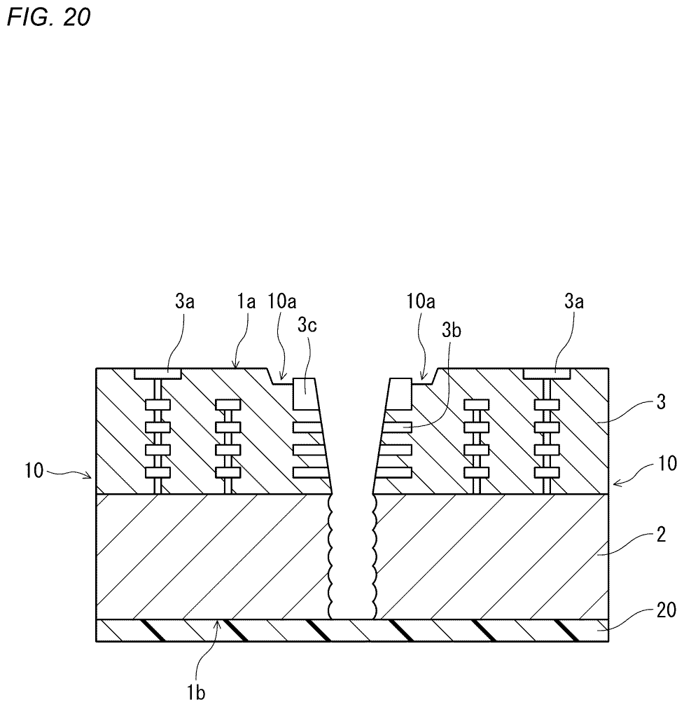

The steps not illustrated herein can be performed in the same manner as in the first embodiment. Even if minute protrusions are present at the edge of the bottom surface of the recess 10a in the element chip 10 (see FIG. 20) that is obtained in the present embodiment, the minute protrusions do not hinder direct bonding between the first substrate 1 and the second substrate 50 by establishing the relative magnitudes of the distances in the thickness direction described above.

### <Supplemental Remarks>

According to the above description of the embodiments, the following techniques are disclosed.

### (Technique 1)

An element chip production method including:
a preparation step of preparing a substrate having a plurality of element regions and a division region defining the element regions, the substrate having a first principal surface and a second principal surface and including a first layer being a semiconductor layer and a second layer formed on a first principal surface side of the first layer and including an insulator;
a planarization step of planarizing an upper surface of the second layer by polishing the first principal surface side of the substrate;
a first protective layer formation step of forming, on the upper surface of the second layer, a first protective layer having a first opening from which the division region is exposed;
a first groove formation step of forming a first groove having a first groove width in the division region by performing etching on a part of the second layer exposed from the first opening;
a supporting step of supporting the second principal surface of the substrate using a support member;
a second protective layer formation step of forming a second protective layer on a surface of the second layer;
a laser grooving step of forming a second groove inside the first groove in the division region by irradiating inside of the first groove with a laser beam from the first principal surface side, the second groove having a second groove width smaller than the first groove width, the second groove penetrating the second protective layer and the second layer and reaching the first layer; and
a dicing step of forming a plurality of element chips each having one of the element regions and a recess at an outer edge on the first principal surface side by dividing the substrate in the second groove in a state in which the second principal surface is supported by the support member.

### (Technique 2)

The element chip production method according to Technique 1, wherein the planarization step is performed before the first protective layer formation step.

### (Technique 3)

The element chip production method according to Technique 1, wherein the planarization step is performed after the first groove formation step.

### (Technique 4)

The element chip production method according to Technique 2, further including
a thinning step of thinning the substrate by grinding a second principal surface side of the substrate after the first groove formation step,
wherein in the supporting step, the second principal surface of the substrate, which has been thinned, is supported using the support member.

### (Technique 5)

The element chip production method according to any one of Techniques 1 to 3, wherein the preparation step includes a thinning step of thinning the substrate by grinding a second principal surface side of the substrate.

### (Technique 6)

The element chip production method according to Technique 2 or 3, further including a thinning step of thinning the substrate by grinding a second principal surface side of the substrate after the planarization step, wherein, in the supporting step, the second principal surface of the substrate, which has been thinned, is supported using the support member.

### (Technique 7)

The element chip production method according to any one of Techniques 1 to 6, wherein the second layer includes a metal pattern that is exposed on a surface of a part of the second layer located in the division region,
the etching on the part of the second layer in the first groove formation step includes sputter etching of etching the insulator and the metal pattern, and
in a thickness direction of the substrate, a maximum distance between a bottom surface of the first groove and the second principal surface is smaller than a distance between the upper surface of the second layer in the element regions and the second principal surface.

### (Technique 8)

The element chip production method according to any one of Techniques 1 to 6, wherein the dicing step includes a plasma dicing step of dividing the substrate by etching the first layer through plasma exposure of the second groove.

### (Technique 9)

The element chip production method according to any one of Techniques 1 to 6, wherein the dicing step includes a laser irradiation step of dividing the substrate by irradiating the second groove with a laser beam.

### (Technique 10)

The element chip production method according to any one of Techniques 1 to 6, wherein the dicing step includes a blade dicing step of dividing the substrate in the second groove using a blade thinner than the second groove width.

### (Technique 11)

A bonded body production method including:
an element chip preparation step of preparing element chips;
a second substrate preparation step of preparing a second substrate; and
a bonding step of bonding one of the element chips to the second substrate,
wherein the element chip preparation step includes;
   a preparation step of preparing a first substrate having a plurality of element regions and a division region defining the element regions, the first substrate having a first principal surface and a second principal surface and including a first layer being a semiconductor layer and a second layer formed on a first principal surface side of the first layer and including an insulator;
   a planarization step of planarizing an upper surface of the second layer by polishing the first principal surface side of the first substrate;
   a first protective layer formation step of forming, on the upper surface of the second layer, a first protective layer having a first opening from which the division region is exposed;
   a first groove formation step of forming a first groove having a first groove width in the division region by performing etching on a part of the second layer exposed from the first opening;
   a supporting step of supporting the second principal surface of the first substrate using a support member;
   a second protective layer formation step of forming a second protective layer on a surface of the second layer;
   a laser grooving step of forming a second groove inside the first groove in the division region by irradiating inside of the first groove with a laser beam from the first principal surface side, the second groove having a second groove width smaller than the first groove width, the second groove penetrating the second protective layer and the second layer and reaching the first layer; and
   a dicing step of forming a plurality of element chips each having one of the element regions and a recess at an outer edge on the first principal surface side by dividing the first substrate in the second groove in a state in which the second principal surface is supported by the support member, and
in the bonding step, the first principal surface side of the element chips is brought into close contact with the second substrate and bonded thereto.

### (Technique 12)

The bonded body production method according to Technique 11, wherein in the element chip preparation step, the planarization step is performed before the first protective layer formation step.

### (Technique 13)

The bonded body production method according to Technique 11, wherein in the element chip preparation step, the planarization step is performed after the first groove formation step.

### (Technique 14)

The bonded body production method according to Technique 12, wherein the element chip preparation step further includes a thinning step of thinning the first substrate by grinding a second principal surface side of the first substrate after the first groove formation step, and
in the supporting step, the second principal surface of the first substrate, which has been thinned, is supported using the support member.

### (Technique 15)

The bonded body production method according to any one of Techniques 11 to 13, wherein the preparation step includes a thinning step of thinning the first substrate by grinding a second principal surface side of the first substrate.

### (Technique 16)

The bonded body production method according to Technique 12 or 13, wherein the element chip preparation step further includes a thinning step of thinning the first substrate by grinding a second principal surface side of the first substrate after the planarization step, and
in the supporting step, the second principal surface of the first substrate, which has been thinned, is supported using the support member.

### (Technique 17)

The bonded body production method according to any one of Techniques 11 to 16, wherein the second layer includes a metal pattern that is exposed on a surface of a part of the second layer located in the division region,
the etching on the part of the second layer in the first groove formation step includes sputter etching of etching the insulator and the metal pattern, and
in a thickness direction of the first substrate, a maximum distance between a bottom surface of the first groove and the second principal surface is smaller than a distance between the upper surface of the second layer in the element regions and the second principal surface.

### (Technique 18)

The bonded body production method according to any one of Techniques 11 to 16, wherein the dicing step includes a plasma dicing step of dividing the first substrate by etching the first layer through plasma exposure of the second groove.

### (Technique 19)

The bonded body production method according to any one of Techniques 11 to 16, wherein the dicing step includes a laser irradiation step of dividing the first substrate by irradiating the second groove with a laser beam.

### (Technique 20)

The bonded body production method according to any one of Techniques 11 to 16, wherein the dicing step includes a blade dicing step of dividing the first substrate in the second groove using a blade thinner than the second groove width.

### INDUSTRIAL APPLICABILITY

The present disclosure can be used in element chip production methods and bonded body production methods.

### REFERENCE NUMERALS

1: First substrate
1a: First principal surface
1b: Second principal surface
2: First layer
3: Second layer
3a: Metal electrode
3b: Metal electrode
3c: Metal pattern
4: First protective layer
4a: First opening
5: First groove
6: Second protective layer
7: Second groove
10: Element chip
10a: Recess
20: Support member
30: Plasma processing apparatus
31: Chamber
32: Antenna
33: First high-frequency power supply
34: Processing room
35: Stage
36: Second high-frequency power supply
37: Gas inlet
38: Source gas supply
39: Exhaust port
40: Vacuum exhaust section
50: Second substrate
51: Semiconductor layer
52: Wiring layer
52a: Metal electrode
D1, D2: Distance in thickness direction
DA: Division region
EA: Element region
W1: First groove width
W2: Second groove-width

What is claimed is:

1. A element chip production method comprising:
a preparation step of preparing a substrate having a plurality of element regions and a division region defining the element regions, the substrate having a first principal surface and a second principal surface and including a first layer being a semiconductor layer and a second layer formed on a first principal surface side of the first layer and including an insulator;
a planarization step of planarizing an upper surface of the second layer by polishing the first principal surface side of the substrate;
a first protective layer formation step of forming, on the upper surface of the second layer, a first protective layer having a first opening from which the division region is exposed;
a first groove formation step of forming a first groove having a first groove width in the division region by performing etching on a part of the second layer exposed from the first opening;
a supporting step of supporting the second principal surface of the substrate using a support member;
a second protective layer formation step of forming a second protective layer on a surface of the second layer;
a laser grooving step of forming a second groove inside the first groove in the division region by irradiating inside of the first groove with a laser beam from the first principal surface side, the second groove having a second groove width smaller than the first groove width, the second groove penetrating the second protective layer and the second layer and reaching the first layer; and
a dicing step of forming a plurality of element chips each having one of the element regions and a recess at an outer edge on the first principal surface side by dividing the substrate in the second groove in a state in which the second principal surface is supported by the support member.

2. The element chip production method according to claim 1,
wherein the planarization step is performed before the first protective layer formation step.

3. The element chip production method according to claim 1,
wherein the planarization step is performed after the first groove formation step.

4. The element chip production method according to claim 2, further comprising
a thinning step of thinning the substrate by grinding a second principal surface side of the substrate after the first groove formation step,
wherein in the supporting step, the second principal surface of the substrate, which has been thinned, is supported using the support member.

5. The element chip production method according to claim 1,
wherein the preparation step includes a thinning step of thinning the substrate by grinding a second principal surface side of the substrate.

6. The element chip production method according to claim 2, further comprising a thinning step of thinning the substrate by grinding a second principal surface side of the substrate after the planarization step,
wherein, in the supporting step, the second principal surface of the substrate, which has been thinned, is supported using the support member.

7. The element chip production method according to claim 1,
wherein the second layer includes a metal pattern that is exposed on a surface of a part of the second layer located in the division region,
the etching on the part of the second layer in the first groove formation step includes sputter etching of etching the insulator and the metal pattern, and
in a thickness direction of the substrate, a maximum distance between a bottom surface of the first groove and the second principal surface is smaller than a distance between the upper surface of the second layer in the element regions and the second principal surface.

8. The element chip production method according to claim 1,
wherein the dicing step includes a plasma dicing step of dividing the substrate by etching the first layer through plasma exposure of the second groove.

9. The element chip production method according to claim 1,
wherein the dicing step includes a laser irradiation step of dividing the substrate by irradiating the second groove with a laser beam.

10. The element chip production method according to claim 1,
wherein the dicing step includes a blade dicing step of dividing the substrate in the second groove using a blade thinner than the second groove width.

11. A bonded body production method comprising:
an element chip preparation step of preparing element chips;
a second substrate preparation step of preparing a second substrate; and
a bonding step of bonding one of the element chips to the second substrate,
wherein the element chip preparation step includes;
a preparation step of preparing a first substrate having a plurality of element regions and a division region defining the element regions, the first substrate having a first principal surface and a second principal surface and including a first layer being a semiconductor layer and a second layer formed on a first principal surface side of the first layer and including an insulator;
a planarization step of planarizing an upper surface of the second layer by polishing the first principal surface side of the first substrate;
a first protective layer formation step of forming, on the upper surface of the second layer, a first protective layer having a first opening from which the division region is exposed;
a first groove formation step of forming a first groove having a first groove width in the division region by performing etching on a part of the second layer exposed from the first opening;
a supporting step of supporting the second principal surface of the first substrate using a support member;
a second protective layer formation step of forming a second protective layer on a surface of the second layer;
a laser grooving step of forming a second groove inside the first groove in the division region by irradiating inside of the first groove with a laser beam from the first principal surface side, the second groove having a second groove width smaller than the first groove width, the second groove penetrating the second protective layer and the second layer and reaching the first layer; and
a dicing step of forming a plurality of element chips each having one of the element regions and a recess at an outer edge on the first principal surface side by dividing the first substrate in the second groove in a state in which the second principal surface is supported by the support member, and
in the bonding step, the first principal surface side of the element chips is brought into close contact with the second substrate and bonded thereto.

12. The bonded body production method according to claim 11,
wherein in the element chip preparation step, the planarization step is performed before the first protective layer formation step.

13. The bonded body production method according to claim 11,
wherein in the element chip preparation step, the planarization step is performed after the first groove formation step.

14. The bonded body production method according to claim 12,
wherein the element chip preparation step further includes a thinning step of thinning the first substrate by grinding a second principal surface side of the first substrate after the first groove formation step, and
in the supporting step, the second principal surface of the first substrate, which has been thinned, is supported using the support member.

15. The bonded body production method according to claim 11,
wherein the preparation step includes a thinning step of thinning the first substrate by grinding a second principal surface side of the first substrate.

16. The bonded body production method according to claim 12,
wherein the element chip preparation step further includes a thinning step of thinning the first substrate by grinding a second principal surface side of the first substrate after the planarization step, and
in the supporting step, the second principal surface of the first substrate, which has been thinned, is supported using the support member.

17. The bonded body production method according to claim 11,
wherein the second layer includes a metal pattern that is exposed on a surface of a part of the second layer located in the division region,
the etching on the part of the second layer in the first groove formation step includes sputter etching of etching the insulator and the metal pattern, and
in a thickness direction of the first substrate, a maximum distance between a bottom surface of the first groove and the second principal surface is smaller than a distance between the upper surface of the second layer in the element regions and the second principal surface.

18. The bonded body production method according to claim 11,
wherein the dicing step includes a plasma dicing step of dividing the first substrate by etching the first layer through plasma exposure of the second groove.

19. The bonded body production method according to claim 11,
wherein the dicing step includes a laser irradiation step of dividing the first substrate by irradiating the second groove with a laser beam.

20. The bonded body production method according to claim 11,
wherein the dicing step includes a blade dicing step of dividing the first substrate in the second groove using a blade thinner than the second groove width.
